(19) United States
(12) Patent Application Publication
(10) Pub. No.: US 2025/0364279 A1
(43) Pub. Date: Nov. 27, 2025

(54) ELECTROSTATIC CHUCK

(71) Applicant: TOTO LTD., Fukuoka (JP)

(72) Inventors: Jumpei UEFUJI, Fukuoka (JP); Tomoki UMETSU, Fukuoka (JP); Masafumi IKEGUCHI, Fukuoka (JP); Kensuke SUZUKI, Fukuoka (JP); Tatsuya MORI, Fukuoka (JP)

(21) Appl. No.: 19/213,371

(22) Filed: May 20, 2025

(30) Foreign Application Priority Data
May 21, 2024 (JP) 2024-082294

(51) Int. Cl. H02N 13/00; B23Q 3/15

(52) U.S. Cl. CPC H01L 21/67103; H01L 21/6833

(57) ABSTRACT

An electrostatic chuck 10 includes a dielectric substrate 100 including a placement surface and a base plate 200 which is joined to the dielectric substrate 100 and which has formed therein a coolant flow path 400 through which a coolant flows. The coolant flow path 400 includes a first flow path 410 and a second flow path 420 connected in series to each other. The second flow path 420 is formed in a position on the dielectric substrate 100 side relative to the first flow path 410 in a direction perpendicular to the placement surface.

### CROSS-REFERENCE TO RELATED APPLICATION

This application is based upon and claims the benefit of priority from Japanese Patent Application No. 2024-082294 filed on May 21, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

During a process such as etching, a temperature of the wafer is to be maintained at an appropriate temperature. For this reason, as described in Japanese Patent Laid-Open No. 2020-161597, a coolant flow path through which a coolant flows is formed inside the base plate.

### SUMMARY

In the electrostatic chuck described in Japanese Patent Laid-Open No. 2020-161597, a routing pathway of the coolant flow path is devised such that an in-plane temperature distribution of a wafer during a process becomes uniform. However, in a configuration of the coolant flow path for causing the in-plane temperature distribution to be uniform, there has been room for further improvement in the electrostatic chuck described in the related art.

The present invention has been made in view of the above-mentioned issue and is aimed to provide an electrostatic chuck which can suppress a variation in an in-plane temperature of a wafer during a process.

To address the above-mentioned issue, an electrostatic chuck according to an aspect of the present invention includes a dielectric substrate including a placement surface on which an object to be attracted is placed, and a base plate which is joined to the dielectric substrate and which has formed therein a coolant flow path through which a coolant flows. The coolant flow path includes a first flow path and a second flow path connected in series to each other. The second flow path is formed in a position on the dielectric substrate side relative to the first flow path in a direction perpendicular to the placement surface.

The second flow path is located in a position closer to a target to be cooled than the first flow path and therefore can efficiently cool down the target to be cooled. That is, cooling performance in the part corresponding to the second flow path can be locally increased. It is noted that the “target to be cooled” is, for example, a wafer such as a silicon wafer, an annual member arranged so as to surround the wafer, or the like. When the second flow path is arranged in a position immediately below a part where a temperature is relatively likely to increase in the target to be cooled, it becomes possible to suppress the variation in the in-plane temperature of the wafer during the process.

According to the aspect of the present invention, it is possible to provide the electrostatic chuck which can suppress the variation in the in-plane temperature of the wafer during the process.

### BRIEF DESCRIPTION OF THE DRAWINGS

FIG. 1 is a cross sectional view schematically illustrating a configuration of an electrostatic chuck according to the present embodiment;

FIG. 2 illustrates a configuration of a coolant flow path formed in a base plate; and

FIG. 3 is an expanded cross sectional view of a part of the configuration of the coolant flow path.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

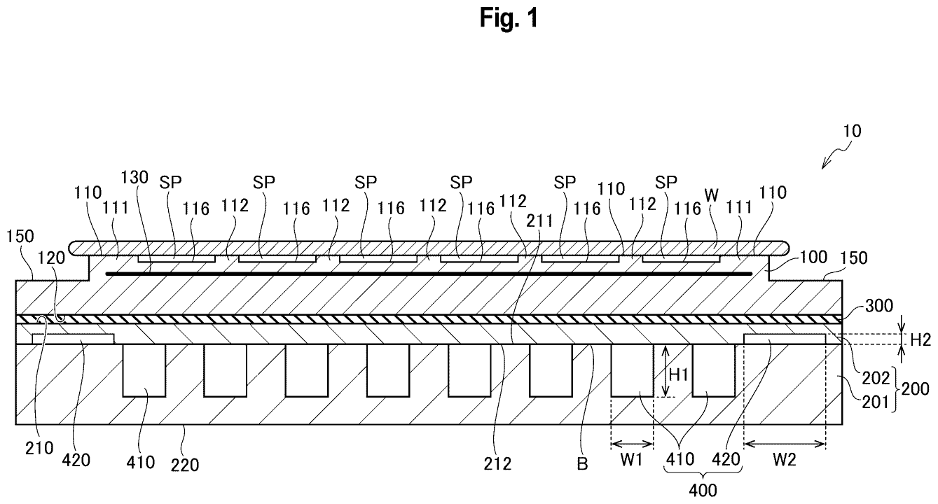

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

An attraction electrode 130 is embedded inside the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various configurations in related art can be adopted. The single attraction electrode 130 may be provided as so-called a “monopolar” electrode as in the present embodiment, but may also include two attraction electrodes as so-called “bipolar” electrodes.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and dots 112 are provided on the surface 110 which serves as the placement surface, and the space SP described above is formed around the seal ring 111 and the dots 112.

The seal ring 111 is a wall which defines the space SP in a position corresponding to an outermost circumference. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign “116” in FIG. 1 is a bottom of the space SP. Hereinafter, this part may also be referred to as a “bottom 116”. The seal ring 111 is formed as a result of recessing a part of the surface 110 to a position of the bottom 116 together with the dots 112 which will be described next.

Each of the dots 112 is a circular protrusion which protrudes from the bottom 116. The dots 112 are provided in plurality, and are substantially uniformly distributed and arranged on the placement surface of the dielectric substrate 100. An upper end of each of the dots 112 becomes a part of the surface 110 and abuts against the wafer W. By providing the plurality of such dots 112, warping of the wafer W can be restrained.

The dielectric substrate 100 of the present embodiment is provided with a rim portion 150. The rim portion 150 is a part protruding further towards the outer circumferential side relative to the surface 110 serving as the placement surface. In top view, the rim portion 150 surrounds the entire surface 110 from an outer side. A surface on the wafer W side (surface on the upper side in FIG. 1) in a rim portion 150 is in a position on the base plate 200 side (lower side in FIG. 1) relative to the surface 110. When the wafer W is processed, an annular member referred to as a “focus ring” or the like which is not illustrated in the drawing is placed on the rim portion 150. Instead of such a mode, a mode may be adopted in which the above-described annular member is directly placed on the base plate 200 without the provision of the rim portion 150 in the dielectric substrate 100.

The base plate 200 is a substantially disk-shaped member which supports the dielectric substrate 100. The base plate 200 is made of, for example, a metallic material such as aluminum. A surface 210 on the upper side in FIG. 1 in the base plate 200 serves as a “surface to be joined” which is joined to the dielectric substrate 100 via the joining layer 300.

The joining layer 300 is a layer provided between the dielectric substrate 100 and the base plate 200 to join those components. The joining layer 300 is obtained by causing an adhesive made of an insulating material to be cured. According to the present embodiment, a silicone adhesive is used as the above-described adhesive. It is noted however that the joining layer 300 may be obtained by causing an adhesive made of other types to be cured. In any case, in order that a thermal resistance between the dielectric substrate 100 and the base plate 200 is reduced, a material with a highest possible thermal conductivity may be used as the material of the joining layer 300.

An insulating film may be formed on a surface of the base plate 200. As the insulating film, for example, an alumina film formed by thermal splaying can be used. When the surface of the base plate 200 is covered by the insulating film, it is possible to increase a withstand voltage of the base plate 200.

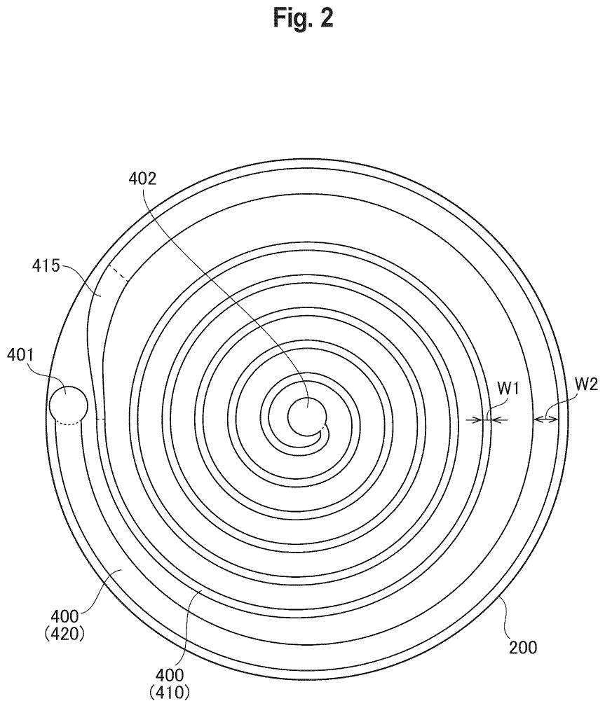

A coolant flow path 400 through which a coolant flows is formed inside the base plate 200. When the process such as etching is performed in the semiconductor manufacturing apparatus, the coolant is supplied from the outside to the coolant flow path 400, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 400 are performed via openings 401 and 402 (which are not illustrated in FIG. 1; see FIG. 2) formed in a surface 220 opposite to the surface 210 in the base plate 200. The coolant flow path 400 is formed so as to pass through not only a range overlapped with the surface 110 in top view but also a part on the outer circumferential side relative to the surface 110. For this reason, not only the wafer W but also the above-described annular member is cooled down by the coolant which passes through the coolant flow path 400.

A configuration of the coolant flow path 400 will be described. FIG. 2 schematically depicts the configuration of the coolant flow path 400 formed inside the base plate 200 in top view. As described above, the openings 401 and 402 are provided in the surface 220 of the base plate 200. The coolant flow path 400 connects the opening 401 and the opening 402 and is formed so as to extend along such a pathway which passes through almost the entirety of the base plate 200 in top view. Both the openings 401 and 402 are circular openings in top view and formed so as to extend perpendicularly to the surface 220 towards the coolant flow path 400 from the surface 220. Internal spaces of the openings 401 and 402 can be regarded as parts of the coolant flow path 400. According to the present embodiment, the coolant is supplied from the outside to the opening 401. The coolant which has passed through the coolant flow path 400 to be supplied and used to cool down the wafer W is discharged from the opening 402 to the outside. A direction in which the coolant flows in the coolant flow path 400 may be a direction opposite to the above-described configuration.

The coolant flow path 400 includes a first flow path 410 and a second flow path 420. The first flow path 410 and the second flow path 420 are connected in series to each other, and the entirety of these is formed so as to extend in a spiral shape in top view.

The first flow path 410 is a part on a downstream side in a direction in which the coolant flows in the coolant flow path 400 and is formed so as to extend from the opening 402 towards an upstream side. The second flow path 420 is a part on the upstream side in a direction in which the coolant flows in the coolant flow path 400 and is formed so as to extend from the opening 401 towards the downstream side. The first flow path 410 and the second flow path 420 are connected in series via a connection flow path 415 which will be described below.

The second flow path 420 is located in an outermost circumferential position in the coolant flow path 400 which has a spiral shape, and extends in a circumferential direction (that is, in an arc shape) in the above-described position. That is, the second flow path 420 is formed in a position on the outer circumferential side relative to the first flow path 410 in top view. As illustrated in FIG. 1, the second flow path 420 is formed in a position immediately below an outermost circumferential part in the wafer W. In top view, a part of the second flow path 420 is overlapped with the surface 110, and another part of the second flow path 420 is overlapped with the rim portion 150.

As illustrated in FIG. 1, according to the present embodiment, the second flow path 420 is formed in a position further on the dielectric substrate 100 side (that is, on the upper side in FIG. 1) compared with the first flow path 410 in the direction perpendicular to the placement surface.

It is noted that the “positions” of the first flow path 410 and the second flow path 420 described above refer to positions of parts on the side closest to the surface 210 (positions on the upper sides in FIG. 1) in the first flow path 410 and the like. Therefore, a positional relationship between the first flow path 410 and the second flow path 420 described above can be rephrased such that a distance from the second flow path 420 to the surface 210 is smaller than a distance from the first flow path 410 to the surface 210.

The connection flow path 415 is a part which connects the first flow path 410 and the second flow path 420. In FIG. 2, each of a boundary between the first flow path 410 and the connection flow path 415 and a boundary between the second flow path 420 and the connection flow path 415 is indicated by a dotted line.

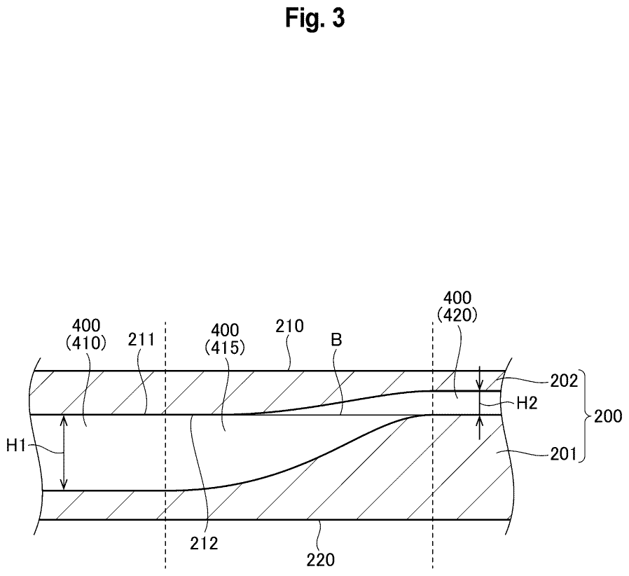

FIG. 3 schematically depicts a cross section in a case where a part where the connection flow path 415 is provided in the base plate 200 and its neighboring part are cut perpendicular to the surface 110. Similarly as in FIG. 2, in FIG. 3 too, each of the boundary between the first flow path 410 and the connection flow path 415 and the boundary between the second flow path 420 and the connection flow path 415 is indicated by a dotted line.

As illustrated in FIG. 3, the connection flow path 415 extends in a direction inclined to the placement surface. According to this, the connection flow path 415 smoothly connects the first flow path 410 and the second flow path 420 which are in the height positions different from each other as described above. The phrase “extends in a direction inclined” described above means that an angle defined by a direction in which the coolant flows in the connection flow path 415 and the placement surface is larger than 0 degrees and smaller than 90 degrees. By forming the connection flow path 415 in this way, a flow path resistance in the coolant flow path 400 as a whole can be suppressed, and a load onto a coolant supply apparatus can be reduced.

An advantage from the arrangement of the second flow path 420 in the position on the dielectric substrate 100 side relative to the first flow path 410 will be described. When the wafer W is processed in the semiconductor manufacturing apparatus, it is known that a temperature in the part on the outer circumferential side in the wafer W is likely to locally increase. However, the local temperature increase of the wafer W is not desirable since this becomes a cause of non-uniformity performance in the process such as etching. Therefore, the coolant flow path 400 needs to be formed such that an in-plane temperature distribution of the wafer W during the process becomes as uniform as possible.

In view of the above, in the present embodiment, the second flow path 420 is arranged in the position immediately below the part where the temperature is likely to locally increase in the target to be cooled. Since the second flow path 420 is located in the position closer to the target to be cooled than the first flow path 410, cooling by the second flow path 420 can be efficiently performed.

It is noted that the “target to be cooled” is, for example, the wafer W, an annual member which is not illustrated in the drawing and which is arranged so as to surround the wafer W, or the like. When the second flow path 420 is arranged in the position immediately below the part where the temperature is relatively likely to increase in the target to be cooled, it becomes possible to suppress the variation in the in-plane temperature of the wafer W during the process.

A dimension of the coolant flow path 400 along a direction perpendicular to the direction in which the coolant flows in the coolant flow path 400 that is a direction parallel to the placement surface (surface 110) will be hereinafter also referred to as a “width dimension” of the coolant flow path 400.

As illustrated in FIG. 2, the first flow path 410 and the second flow path 420 are different from each other also in terms of the width dimension. Specifically, W2 which denotes a width dimension of the second flow path 420 is larger than W1 which denotes a width dimension of the first flow path 410. In the connection flow path 415, as the flow path goes farther from the first flow path 410 side to the second flow path 420 side, the width dimension of the coolant flow path 400 smoothly changes from W1 to W2.

A dimension of the coolant flow path 400 along a direction perpendicular to the placement surface (surface 110) will be hereinafter also referred to as a “height dimension” of the coolant flow path 400. As illustrated in FIG. 3, the first flow path 410 and the second flow path 420 are different from each other in terms of not only the width dimension but also the height dimension. Specifically, H2 which denotes a height dimension of the second flow path 420 is smaller than H1 which denotes a height dimension of the first flow path 410. In the connection flow path 415, as the flow path goes farther from the first flow path 410 side to the second flow path 420 side, the height dimension of the coolant flow path 400 smoothly changes from H1 to H2.

As described above, the connection flow path 415 forms a portion that smoothly connects the first flow path 410 and the second flow path 420 which are different from each other in both the width dimension and the height dimension.

As illustrated in FIG. 1, in the first flow path 410, the width dimension (W1) of the coolant flow path 400 is smaller than the height dimension (H1). On the other hand, in second flow path 420, the width dimension (W2) of the coolant flow path 400 is larger than the height dimension (H2). A part having the width dimension larger than the height dimension in the coolant flow path 400 will be hereinafter also referred to as a “flattened portion”. According to the present embodiment, the entire second flow path 420 corresponds to the flattened portion.

In the present embodiment, the second flow path 420 is arranged in the position immediately below the part where the local temperature increase is likely to occur, and furthermore, the second flow path 420 is formed to be the flattened portion. In the flattened portion, since a flow speed of the coolant is increased as a result of the suppression in the height dimension of the coolant flow path 400, the part immediately above the flattened portion can be efficiently cooled down. Since most of the coolant which passes through the flattened portion passes through a position near the target to be cooled in the upper side, the further efficient cooling can be performed. As a result, the variation in the in-plane temperature of the wafer W during the process can be sufficiently reduced.

It is noted that in the part where the relatively high cooling performance is demanded as in the position immediately below the part on the outer circumferential side of the wafer W, instead of arranging the flattened portion as described above, the flow speed of the coolant can be increased to increase the cooling performance by sufficiently reducing the width dimension of the coolant flow path 400 in the above-described part too. However, in a case where such a configuration is adopted, since a length of the entire coolant flow path 400 is lengthened and the flow path resistance is increased, an issue may occur that the load on the coolant supply apparatus which is not illustrated in the drawing is increased. On the other than, in a case where a part of the coolant flow path 400 is formed to be the flattened portion to increase the cooling performance as in the present embodiment, since the length of the entire coolant flow path 400 does not need to be extended along with the configuration, the above-described issue does not occur.

As a ratio of the height dimension to the width dimension of the coolant flow path 400 is decreased, the cooling performance of the coolant flow path 400 can be increased. According to an experiment conducted by the present inventors of the present invention, it is confirmed that when the flattened portion is formed such that the width dimension of the coolant flow path 400 becomes five or more times the height dimension, the cooling performance in the above-described part may be sufficiently increased. When the width dimension of the coolant flow path 400 is set to be six or more times the height dimension, the cooling performance can be further increased.

The flattened portion can be provided in any part in the coolant flow path 400. As described above, according to the present embodiment, a configuration is adopted in which the entirety of the second flow path 420 in the coolant flow path 400, that is, the entirety of the part extending in the circumferential direction in the position corresponding to the outermost circumference in the coolant flow path 400 is formed to be the flattened portion. When such a configuration is adopted, the outermost circumferential part of the wafer W, the annular member installed further on the outer side, or the like can be efficiently cooled down. As a result, the in-plane temperature distribution of the wafer W can be set to be uniform.

It is noted that it is sufficient when only a part of the coolant flow path 400 is formed as the flattened portion, but the entirety may be formed as the flattened portion. That is, the entirety of the coolant flow path 400 may be formed such that the width dimension is larger than the height dimension.

To facilitate the formation of the relatively complex coolant flow path 400, the base plate 200 of the present embodiment is formed by joining a plurality of members to each other. Specifically, the base plate 200 is formed by mutually joining two members including a first member 201 and a second member 202 to be integrated. Each member is joined by welding, but for example, each member may be joined by a method such as brazing or fastening and fixing. The number of members constituting the base plate 200 may be three or more.

As illustrated in FIG. 1, the first member 201 and the second member 202 are aligned in the stated order along the direction perpendicular to the surface 110 serving as the placement surface. The second member 202 is a member arranged on the dielectric substrate 100 side, and the first member 201 is a member arranged on the opposite side. The surface 210 described above is a part of the second member 202, and the surface 220 is a part of the first member 201. A joint boundary B between the first member 201 and the second member 202 is parallel to the surface 210 and the surface 220. In this way, the base plate 200 of the present embodiment is configured by joining the first member 201 and the second member 202 located on the dielectric substrate 100 side relative to the first member 201.

As illustrated in FIG. 1 and FIG. 3, the first flow path 410 according to the present embodiment is entirely formed in the first member 201. The first flow path 410 is a groove which has been formed in advance in the surface 211 on the second member 202 side in the first member 201 before the first member 201 and the second member 202 are joined. The surface 211 is a surface serving as the joint boundary B after the joining. In the part corresponding to the connection flow path 415, the groove in the surface 211 described above is formed so as to be gradually shallower as the flow path farther goes from the first flow path 410 side to the second flow path 420 side.

The second flow path 420 according to the present embodiment is entirely formed in the second member 202. The second flow path 420 is a groove which has been formed in advance in the surface 212 on the first member 201 side in the second member 202 before the first member 201 and the second member 202 are joined. The surface 212 is a surface serving as the joint boundary B after the joining. In the part corresponding to the connection flow path 415, the groove in the surface 212 described above is formed so as to be gradually deeper as the flow path farther goes from the first flow path 410 side to the second flow path 420 side.

In this way, the base plate 200 is formed by joining the members with the grooves which have been formed in advance to each other. According to this, the coolant flow path 400 with the relatively complex shape can be easily formed inside the base plate 200.

The example has been described above in which the second flow path 420 is formed in the position on the dielectric substrate 100 side relative to the first flow path 410 and the second flow path 420 is formed to be the flattened portion. Instead of such a mode, a mode may be adopted in which the flattened portion is not provided in the coolant flow path 400, that is, the second flow path 420 is formed in the position on the dielectric substrate 100 side relative to the first flow path 410 and in the entire coolant flow path 400, the width dimension is smaller than the height dimension.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed; and
a base plate which is joined to the dielectric substrate and which has formed therein a coolant flow path through which a coolant flows, wherein
the coolant flow path includes a first flow path and a second flow path connected in series to each other, and
the second flow path is
formed in a position on the dielectric substrate side relative to the first flow path in a direction perpendicular to the placement surface.

2. The electrostatic chuck according to claim 1, wherein
when viewed from the direction perpendicular to the placement surface,
the second flow path is formed in a position on an outer circumferential side relative to the first flow path.

3. The electrostatic chuck according to claim 1, wherein
a part which connects the first flow path and the second flow path in the coolant flow path extends in a direction inclined to the placement surface.

4. The electrostatic chuck according to claim 1, wherein
a width dimension of the second flow path is larger than a height dimension of the second flow path.

5. The electrostatic chuck according to claim 4, wherein
the width dimension of the second flow path is five or more times the height dimension of the second flow path.

6. The electrostatic chuck according to claim 1, wherein
the base plate is configured by joining a first member and a second member located on the dielectric substrate side relative to the first member,
the first flow path is formed in the first member, and
the second flow path is formed in the second member.

7. The electrostatic chuck according to claim 6, wherein
the first flow path is a groove formed in a surface on the second member side in the first member, and
the second flow path is a groove formed in a surface on the first member side in the second member.
